(19) United States
(12) Patent Application Publication
(10) Pub. No.: US 2024/0169946 A1
(43) Pub. Date: May 23, 2024

(54) DISPLAY DEVICE AND BRIGHTNESS ADJUSTMENT METHOD THEREOF

(71) Applicant: Wuhan China Star Optoelectronics Technology Co., Ltd., Wuhan, Hubei (CN)

(72) Inventors: Yibo BAI, Wuhan, Hubei (CN); Jun LI, Wuhan, Hubei (CN); Delin YANG, Wuhan, Hubei (CN); Yang FENG, Wuhan, Hubei (CN)

(73) Assignee: Wuhan China Star Optoelectronics Technology Co., Ltd., Wuhan, Hubei (CN)

(21) Appl. No.: 17/772,603

(22) PCT Filed: Apr. 13, 2022
(86) PCT No.: PCT/CN2022/086615

§ 371 Date: Apr. 28, 2022

(30) Foreign Application Priority Data
Mar. 22, 2022 (CN) 202210285664.1

(51) Int. Cl. G09G 3/36; G02F 1/1333; G02F 1/153

(52) U.S. Cl. CPC G09G 3/3607; G02F 1/13338; G02F 1/153; G09G 2320/0233

(57) ABSTRACT

The present invention provides a display device and a brightness adjustment method of the display device. The display device includes a light-emitting surface, the display device includes a camera area and a display area, a display panel, and a light transmittance adjustment layer disposed on a side of the display panel close to the light-emitting surface. The light transmittance adjustment layer includes a first adjustment area corresponding to the camera area and a second adjustment area corresponding to the display area. In the present invention, a light transmittance of the first adjustment area and/or a light transmittance of the second adjustment area of the light transmittance adjustment layer is/are adjusted, so that a brightness of different areas of the light-emitting surface is kept uniformity.

### BACKGROUND OF INVENTION

### Field of Invention

The present application relates to a field of display technology, and more particularly to a display device and a brightness adjustment method thereof.

### Description of Prior Art

An under-screen camera technology increases a screen-to-body ratio by placing a camera under a screen, and at a same time makes an entire display device have better aesthetics, so it has been more and more widely used. An existing under-screen camera technology generally improves a light transmittance in this area by opening a hole at a position of a display device corresponding to a camera and making an area of a screen corresponding to the camera have no pixels or reducing pixel arrangement, so as to realize an under-screen camera function.

However, an opening hole design and a pixel arrangement design of the existing under-screen camera technology in the display device corresponding to a camera area will result in inconsistent light transmittance or brightness of the display device corresponding to the camera area and a display area outside the camera area. As a result, even when the display device displays a black image or does not display, screen brightness in the camera area will be significantly different from other areas, so that a blind hole at the camera area is easily observed, affecting aesthetics of the screen.

Therefore, it is necessary to provide a technical solution to solve above problem.

### SUMMARY OF INVENTION

The present invention provides a display device and a brightness adjustment method thereof, which can solve a technical problem of uneven screen brightness of an existing display device due to a difference in luminous flux between a camera area and a display area outside the camera area.

For solving the above problem, technical solutions provided by the present invention are as follows:

The present application provides a display device, wherein, the display device includes a light-emitting surface, the display device includes a camera area and a display area surrounding the camera area, the display device further includes:
a display panel;
a light transmittance adjustment layer disposed on a side of the display panel close to the light-emitting surface, and the light transmittance adjustment layer including a first adjustment area corresponding to the camera area and a second adjustment area corresponding to the display area;
wherein, the display device adjusts a brightness of the light-emitting surface by adjusting a light transmittance of the first adjustment area and/or a light transmittance of the second adjustment area.

Optionally, in some embodiments of the present application, the light transmittance adjustment layer includes a driving wiring layer and a light adjustment layer, and the light adjustment layer receives a voltage input from the driving wiring layer to adjust a light transmittance of the light transmittance adjustment layer.

Optionally, in some embodiments of the present application, the driving wiring layer includes first driving wirings corresponding to the first adjustment area and second driving wirings corresponding to the second adjustment area, and the light adjustment layer receives a voltage input from the first driving wirings and/or a voltage input from the second driving wirings to adjust a light transmittance of a corresponding area of the light transmittance adjustment layer.

Optionally, in some embodiments of the present application, the first driving wirings include first wirings arranged along a first direction and second wirings disposed along a second direction, the first wirings and the second wirings are located on a same side or different sides of the light adjustment layer, the light adjustment layer receives a voltage input from the first wirings and the second wirings to adjust the light transmittance of the first adjustment area;
the second driving wirings include third wirings arranged along a first direction and fourth wirings arranged along a second direction, the third wirings and the fourth wirings are located on a same side or different sides of the light adjustment layer, the light adjustment layer receives a voltage input from the third wirings and the fourth wirings to adjust the light transmittance of the second adjustment area; wherein, the first direction and the second direction are perpendicular to each other.

Optionally, in some embodiments of the present application, the light adjustment layer is a liquid crystal layer or an electrochromic layer.

Optionally, in some embodiments of the present application, the light transmittance adjustment layer further includes a first substrate layer and a second substrate layer disposed oppositely, the light adjustment layer is disposed between the first substrate layer and the second substrate layer, and the driving wiring layer is disposed on a surface of a side of at least one of the first substrate layer and the second substrate layer facing the light adjustment layer.

An embodiment of the present invention also provides a brightness adjustment method for the display device as described above, and the brightness adjustment method includes following steps:
S1: acquiring a display state information of the display device;
wherein, the display state information includes a display state and a non-display state;
S2: determining a target brightness of the light-emitting surface corresponding to the camera area and the display area according to the display state information;
S3: adjusting the light transmittance of the first adjustment area and/or the light transmittance of the second adjustment area according to the target brightness.

Optionally, in some embodiments of the present application, when the display state information being acquired is the display state, the step S1 further includes following steps:
S11: reading an input picture information input to the display device;
the step S2 includes following steps:
S21: acquiring a gray-scale data of an input picture according to the input picture information;
wherein, the gray-scale data includes a first part of gray-scale data of the input picture corresponding to the camera area and a second part of gray-scale data of the input picture corresponding to the display area;
S22: determining a target brightness of the light-emitting surface corresponding to the camera area according to the first part of gray-scale data, and determining a target brightness of the light-emitting surface corresponding to the display area according to the second part of gray-scale data.

Optionally, in some embodiments of the present application, the light transmittance adjustment layer includes a driving wiring layer and a light adjustment layer, and the driving wiring layer includes first driving wirings corresponding to the first adjustment area and second driving wirings corresponding to the second adjustment area, and the step S3 includes following steps:
the light adjustment layer receiving a voltage input from the first driving wiring to adjust the light transmittance of the first adjustment area according to the target brightness of the camera area, and/or the light adjustment layer receiving a voltage input from the second driving wiring to adjust the light transmittance of the second adjustment area according to the target brightness of the display area.

Optionally, in some embodiments of the present application, when the display state information being acquired is the non-display state, the step S1 further includes following steps:
S11: reading a preset black picture information;
the step S2 includes following steps:
S21: obtaining a gray-scale data of a preset black picture according to the preset black picture information;
S22: determining the target brightness of the light-emitting surface corresponding to the camera area and the display area according to the grayscale data.

Optionally, in some embodiments of the present application, the light transmittance adjustment layer includes a driving wiring layer and a light adjustment layer, and the driving wiring layer includes first driving wirings corresponding to the first adjustment area and second driving wirings corresponding to the second adjustment area, the step S3 includes following steps:
receiving, by the light adjustment layer, a voltage input from the first driving wirings to adjust the light transmittance of the first adjustment area according to the target brightness of the camera area, and/or receiving, by the light adjustment layer, a voltage input from the second driving wirings to adjust the light transmittance of the second adjustment area according to a target brightness of the display area.
the present invention further provides a display device, the display device includes a light-emitting surface, the display device includes a camera area and a display area surrounding the camera area, the display device further includes:
a display panel;
a light transmittance adjustment layer disposed on a side of the display panel close to the light-emitting surface, and the light transmittance adjustment layer including a first adjustment area corresponding to the camera area and a second adjustment area corresponding to the display area;
wherein, a light transmittance of the first adjustment area and a light transmittance of the second adjustment area can be adjusted independently, the display device adjusts a brightness of the light-emitting surface by adjusting a light transmittance of the first adjustment area and/or a light transmittance of the second adjustment area.

Optionally, in some embodiments of the present application, the light transmittance adjustment layer includes a driving wiring layer and a light adjustment layer, and the light adjustment layer receives a voltage input from the driving wiring layer to adjust a light transmittance of the light transmittance adjustment layer.

Optionally, in some embodiments of the present application, the driving wiring layer includes first driving wirings corresponding to the first adjustment area and second driving wirings corresponding to the second adjustment area, and the light adjustment layer receives a voltage input from the first driving wirings and/or a voltage input from the second driving wirings to adjust a light transmittance of a corresponding area of the light transmittance adjustment layer.

Optionally, in some embodiments of the present application, the first driving wirings include first wirings arranged along a first direction and second wirings arranged along a second direction, the first wirings and the second wirings are located on a same side or different sides of the light adjustment layer, the light adjustment layer receives a voltage input from the first wirings and a voltage input from the second wiring to adjust the light transmittance of the first adjustment area;
the second driving wirings includes third wirings arranged along a first direction and fourth wirings arranged along a second direction, the third wirings and the fourth wirings are located on a same side or different sides of the light adjustment layer, the light adjustment layer receives a voltage input from the third wiring and a voltage input from the fourth wirings to adjust the light transmittance of the second adjustment area; wherein, the first direction and the second direction are perpendicular to each other.

Optionally, in some embodiments of the present application, the light adjustment layer is a liquid crystal layer or an electrochromic layer.

Optionally, in some embodiments of the present application, the light transmittance adjustment layer further includes a first substrate layer and a second substrate layer disposed oppositely, the light adjustment layer is disposed between the first substrate layer and the second substrate layer, and the driving wiring layer is disposed on a surface of a side of at least one of the first substrate layer and the second substrate layer facing the light adjustment layer.

### Advantageous Effects

The beneficial effects of the present invention are: The present invention provides the display device and the brightness adjustment method thereof. The light transmittance adjustment layer is disposed on the side of the display panel close to the light-emitting surface, and the light transmittance adjustment layer is divided into the first adjustment area corresponding to the camera area and the second adjustment area corresponding to the display area. The over-rate adjustment layer can realize the regional adjustment of light transmittance, and the light transmittance of the light transmittance adjustment layer can be controlled in different areas. By adjusting the light transmittance of the first adjustment area and/or the light transmittance of the second adjustment area of the light transmittance adjustment layer, a luminous flux emitted from the display panel to the light-emitting surface of the display device can be adjusted, so that a brightness of the different areas of the light-emitting surface is consistent, and the brightness of the light-emitting surface of the display device can be adjusted, realizing a brightness adjustment of the light-emitting surface of the display device, thereby solving a problem of uneven brightness of the light-emitting surface of the display device caused by a difference in luminous flux in different area of the display panel.

### BRIEF DESCRIPTION OF DRAWINGS

In order to more clearly illustrate the embodiments or the technical solutions of the existing art, the drawings illustrating the embodiments or the existing art will be briefly described below. The drawings in the following description merely illustrate some embodiments of the present application. Other drawings may also be obtained by those skilled in the art according to these figures without paying creative work.

FIG. 1 is a schematic structural diagram of a display device provided by an embodiment of the present invention.

FIG. 2 is a schematic cross-sectional diagram of a display device of a first embodiment provided by the present invention.

FIG. 3 is a schematic cross-sectional diagram of a display device of a second embodiment provided by the present invention.

FIG. 4 is a schematic cross-sectional diagram of a light transmittance adjustment layer provided by an embodiment of the present invention.

FIG. 5 is a partial schematic diagram of a driving wiring layer provided by an embodiment of the present invention.

FIG. 6 is a schematic cross-sectional diagram of a light transmittance adjustment layer provided by an embodiment of the present invention when no voltage is applied.

FIG. 7 is a schematic cross-sectional diagram of a light transmittance adjustment layer provided by an embodiment of the present invention when a voltage is applied.

FIG. 8 is a flowchart of a brightness adjustment method of a display device provided by an embodiment of the present invention.

### DETAILED DESCRIPTION OF PREFERRED EMBODIMENTS

The technical solutions in the embodiments of the present application will be clearly and completely described below in conjunction with the drawings in the embodiments of the present application. Obviously, the described embodiments are only a part of the embodiments of the present application, rather than all the embodiments. Based on the embodiments in the present application, all other embodiments obtained by those skilled in the art without creative work shall fall within the protection scope of this application. In addition, it should be understood that the specific implementations described here are only used to illustrate and explain the application, and are not used to limit the present application. In the present application, if no explanation is made to the contrary, the orientation words used such as “upper” and “lower” generally refer to the upper and lower positions of the device in actual use or working state, and specifically refer to the drawing directions in the drawings; and “inner” and “outer” refer to the outline of the device.

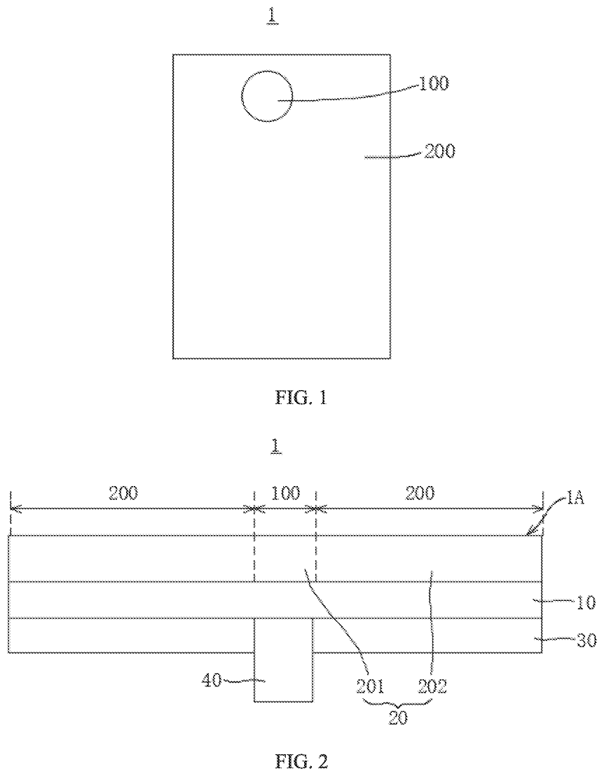

Referring to FIG. 1 to FIG. 7, an embodiment of the present invention provides a display device 1, the display device 1 includes a light-emitting surface 1A, and the display device 1 includes a camera area 100 and a display area 200 surrounding the camera area 100. The display device 1 further includes a display panel 10 and a light transmittance adjustment layer 20, and the light transmittance adjustment layer 20 is disposed on a side of the display panel 10 close to the light-emitting surface 1A. The light transmittance adjustment layer 20 includes a first adjustment area 201 corresponding to the camera area 100 and a second adjustment area 202 corresponding to the display area 200. Wherein, a light transmittance of the first adjustment area 201 and a light transmittance of the second adjustment area 202 can be adjusted independently, the display device 1 adjusts a brightness of the light-emitting surface 1A by adjusting a light transmittance of the first adjustment area 201 and/or a light transmittance of the second adjustment area 202.

It should be noted that, a definition of the camera area 100 and the display area 200 in this embodiment of the present application is from a perspective of area division, and the camera area 100 can actually be designed without pixels according to a type of the display panel 10, or designed with a reduced pixel density, that is, both the camera area 100 and the display area 200 may have a display function, or the camera area 100 may not have the display function.

In the embodiment of the present invention, the light transmittance adjustment layer 20 is disposed on the side of the display panel 10 close to the light-emitting surface. The light transmittance adjustment layer 20 is divided into a first adjustment area 201 corresponding to the camera area 100 and a second adjustment area 202 corresponding to the display area 200, and light transmittance of the light transmittance adjustment layer 20 can be controlled in different areas. By adjusting the light transmittance of the first adjustment area 201 and/or the light transmittance of the second adjustment area 202 of the light transmittance adjustment layer 20, a luminous flux emitted from the display panel 10 to the light-emitting surface 1A of the display device can be adjusted, so that a brightness of the different areas of the light-emitting surface 1A is kept consistent, and brightness adjustment of the light-emitting surface 1A of the display device 1 can be realized, thereby solving a problem of uneven brightness of the light-emitting surface of the display device caused by a difference in luminous flux in different area of the display panel.

The following describes in detail with reference to specific embodiments, which are specifically described as follows.

Please refer to FIG. 1, the display device 1 may be a liquid crystal display device, an OLED display device, a micro-LED display device, or a mini-LED display device, but is not limited to these. The display device 1 includes the camera area 100 and the display area 200 surrounding the camera area 100. It can be understood that, the display area 200 is used for displaying images; the camera area 100 is used for photographing by a camera, and the camera area 100 can also be used for displaying images.

Please refer to FIG. 2, FIG. 2 is a schematic cross-sectional diagram of the display device of a first embodiment provided by the present invention. The display device 1 includes the display panel 10, the light transmittance adjustment layer 20, a backlight module 30, and a camera 40. The display panel 10 is a liquid crystal display panel, the light transmittance adjustment layer 20 is disposed on the side of the display panel 10 close to the light-emitting surface 1A, and the backlight module 30 is disposed on a side of the display panel 10 away from the light-emitting surface 1A. Wherein, a position of the backlight module 30 corresponding to the camera area 100 is defined with an opening hole through the backlight module 30, and the camera 40 is located at the opening hole.

In this embodiment, a blind hole may be defined at an area of the display panel 10 corresponding to the camera area 100, and pixels or no pixels may be disposed on the display panel 10 corresponding to the camera area 100. When the display panel 10 disposes the pixels corresponding to the camera area 100, in order to ensure a shooting performance of the camera, generally, a pixel density of the display panel 10 corresponding to the camera area 100 is less than a pixel density corresponding to the display area 200.

Wherein, since the backlight module 30 is designed with the opening hole in the camera area 100, the display panel 10 in the camera area has no backlight or less backlight illumination, therefore, a luminous flux of the display panel 10 corresponding to the camera area 100 is different from a luminous flux of the display panel 10 corresponding to the display area 200. In addition, due to the blind hole design on the display panel 10, even when the display device does not display, the blind hole in the camera area 100 is easily observed, which affects an aesthetics of a screen.

In the display device of this embodiment, the light transmittance adjustment layer 20 is disposed on the side of the display panel 10 close to the light-emitting surface 1A. By adjusting the light transmittance of the first adjustment area 201 and/or the light transmittance of the second adjustment area 202 of the light transmittance adjustment layer 20, the luminous flux emitted from the display panel 10 to the light-emitting surface 1A of the display device can be adjusted, so that the brightness of the different areas of the light-emitting surface 1A is kept consistent, and the brightness adjustment of the light-emitting surface 1A of the display device 1 can be realized, the display effect is improved, and at a same time, the blind hole can be prevented from being easily observed.

Please refer to FIG. 3, FIG. 3 is a schematic cross-sectional diagram of the display device of a second embodiment provided by the present invention. The display device 1 includes the display panel 10, the light transmittance adjustment layer 20, and the camera 40. The display panel 10 may be the OLED display panel, the micro-LED display panel, or the mini-LED display panel, but is not limited to these. The light transmittance adjustment layer 20 is disposed on the side of the display panel 10 close to the light-emitting surface 1A, the camera 40 is disposed on the side of the display panel 10 away from the light-emitting surface 1A, and the camera 40 corresponds to the camera area 100.

In this embodiment, the blind hole may be defined in the display panel 10 corresponding to the camera area 100, the display panel 10 may be disposed with the pixels corresponding to the camera area 100, and the display panel 10 may not be disposed with the pixels corresponding to the camera area 100. When the display panel 10 disposed the pixels corresponding to the camera area 100, the pixel density of the display panel 10 corresponding to the camera area 100 is less than the pixel density corresponding to the display area 200.

Wherein, since the display panel 10 corresponding to the camera area 100 is designed without pixel or with the pixel density less than the pixel density of the display area 200, therefore, the luminous flux of the display panel 10 corresponding to the camera area 100 is different from the luminous flux of the display panel 10 corresponding to the display area 200. In addition, when the display device does not display, the blind hole in the camera area 100 is easily observed.

In the display device of this embodiment, the light transmittance adjustment layer 20 is disposed on the side of the display panel 10 close to the light-emitting surface 1A. By adjusting the light transmittance of the first adjustment area 201 and/or the light transmittance of the second adjustment area 202 of the light transmittance adjustment layer 20, the luminous flux emitted from the display panel 10 to the light-emitting surface 1A of the display device can be adjusted, so that the brightness of the different areas of the light-emitting surface 1A is kept consistent, and the brightness adjustment of the light-emitting surface 1A of the display device 1 can be realized, and the display effect is improved, and at a same time, the blind hole can be prevented from being easily observed.

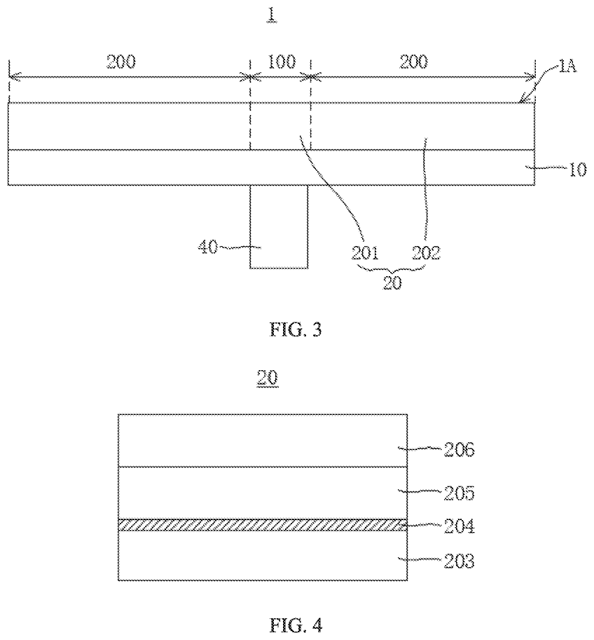

Please refer to FIG. 4. FIG. 4 is a schematic cross-sectional diagram of a light transmittance adjustment layer provided by an embodiment of the present invention. The light transmittance adjustment layer 20 includes a first substrate layer 203 and a second substrate layer 206 disposed opposite to each other, a driving wiring layer 204 and a light adjustment layer 205 located between the first substrate layer 203 and the second substrate layer 206. The driving wiring layer 204 may be disposed on a surface of a side of at least one of the first substrate layer 203 and the second substrate layer 206 facing the light adjustment layer 205. It is illustrated in FIG. 4 that the driving wiring layer 204 is disposed on a surface of a side of the first substrate layer 203 facing the light adjustment layer 205. Wherein, the light adjustment layer 205 receives a voltage input from the driving wiring layer 204 to adjust a light transmittance of the light transmittance adjustment layer 20.

As an embodiment, the light transmittance adjustment layer 20 may be a glass cover plate, and the first substrate layer 203 and the second substrate layer 206 are both glass substrate layers. That is to say, in this embodiment, the driving wiring layer 204 and the light adjustment layer 205 can be sandwiched in glass cover plates.

As an embodiment, the light transmittance adjustment layer 20 may be a polarizer, and the first substrate layer 203 and the second substrate layer 206 are both polarizing layers. That is to say, in this embodiment, the driving wiring layer 204 and the light adjustment layer 205 can be sandwiched in polarizers.

As an embodiment, the light adjustment layer 205 is the liquid crystal layer, and the liquid crystal layer is turned over by a voltage applied to the driving wiring layer 204 to adjust a light transmittance.

As an embodiment, the light adjustment layer 205 is an electrochromic layer, and the electrochromic layer adjusts the light transmittance by a voltage applied on the driving wiring layer 204.

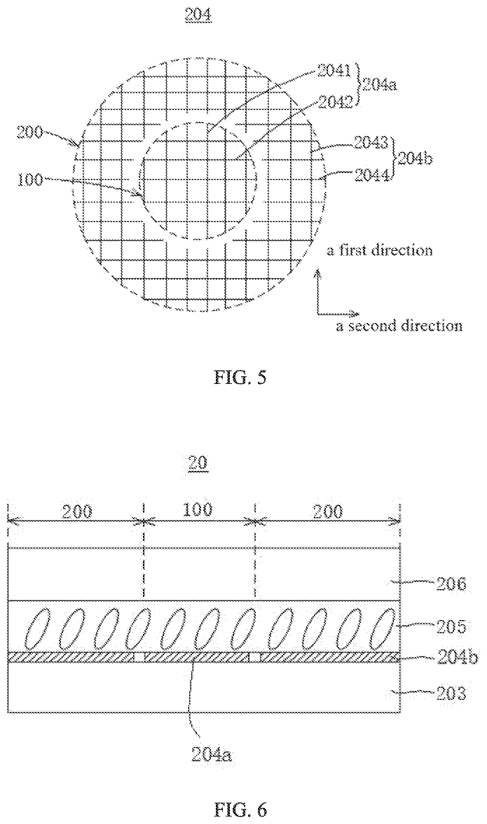

Please refer to FIG. 5, FIG. 5 is a partial schematic diagram of a driving wiring layer provided by an embodiment of the present invention. Wherein, the driving wiring layer 204 includes first driving wirings 204a corresponding to the first adjustment area 201 and second driving wirings 204b corresponding to the second adjustment area 202, and the light adjustment layer 205 receives a voltage input from the first driving wirings 204a and/or a voltage input from the second driving wirings 204b to adjust the light transmittance of the corresponding area of the light transmittance adjustment layer 20.

Specifically, the first driving wirings 204a include first wirings 2041 arranged along a first direction and second wirings 2042 arranged along a second direction, the first wirings 2041 and the second wirings 2042 are located on a same side or different sides of the light adjustment layer 205, the light adjustment layer 205 receives a voltage input from the first wirings 2041 and the second wirings 2042 to adjust the light transmittance of the first adjustment area 201. The second driving wirings 204b include third wirings 2043 arranged along a first direction and fourth wirings 2044 arranged along a second direction, the third wirings 2043 and the fourth wirings 2044 are located on a same side or different sides of the light adjustment layer 205, the light adjustment layer 205 receives a voltage input from the third wirings 2043 and the fourth wirings 2044 to adjust the light transmittance of the second adjustment area 202. Wherein, the first direction and the second direction are perpendicular to each other.

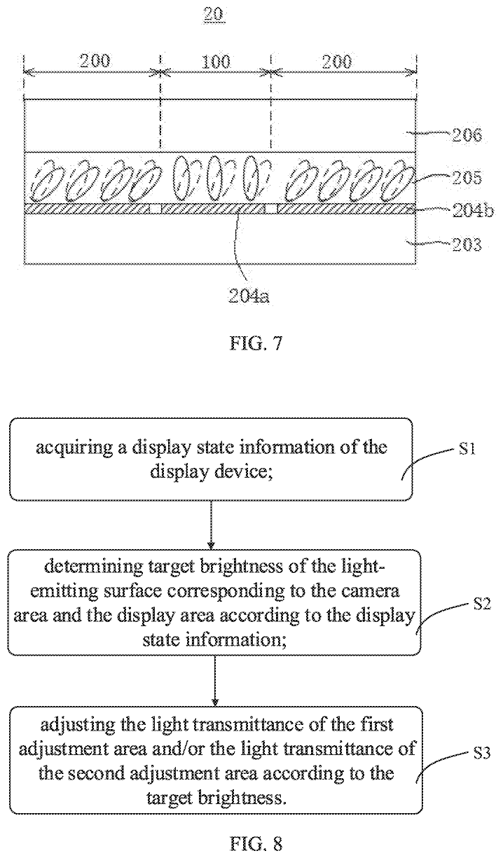

Please refer to FIG. 6 and FIG. 7. FIG. 6 is a schematic cross-sectional diagram of a light transmittance adjustment layer provided by an embodiment of the present invention when no voltage is applied, FIG. 7 a schematic cross-sectional diagram of a light transmittance adjustment layer provided by an embodiment the present invention when a voltage is applied. Here, the display device is the liquid crystal display device as an example. The light transmittance of the display panel 10 corresponding to the camera area 100 is less than the light transmittance corresponding to the display area 200. When no voltage is applied to the light transmittance adjustment layer 20, liquid crystal molecules in the light transmittance adjustment layer 205 are disposed at a preset tilt angle, and the light transmittance adjustment layer 20 has certain transmittance at this time.

When the display device inputs a corresponding voltage to the first driving wirings 204a, the liquid crystal layer inverts liquid crystals corresponding to the first adjustment area by a first angle through a voltage applied to the first driving wiring 204a, thereby improving the light transmittance of the light transmittance adjustment layer 20 corresponding to the camera area 100. At a same time, the display device inputs a corresponding voltage to the second driving wirings 204b, and the liquid crystal layer inverts the liquid crystals corresponding to the second adjustment area by a second angle through the voltage applied to the second driving wirings 204b, thereby reducing the light transmittance of the light transmittance adjustment layer 20 corresponding to the display area 200. Among them, the dotted line in FIG. 7 represents an arrangement of the liquid crystals when no voltage is applied. By adopting such a design, brightness transition between the camera area 100 and the display area 200 of the display device can be made smooth, and a difference in brightness between the camera area 100 and the display area 200 of the display device can be reduced or eliminated, the brightness uniformity of the light-emitting surface of the display device is realized, and the problem that the blind hole of the display device corresponding to the camera area 100 is seen is also solved.

An embodiment of the present invention further provides a brightness adjustment method of the display device as described above. As shown in FIG. 8, the brightness adjustment method of the display device includes following steps:

S1: Acquiring a display state information of the display device.

Wherein, the display state information includes a display state and a non-display state. It can be understood that the display state is a state in which the display panel performs image display when the display panel receives input image information, and the non-display state is a state in which the display panel does not perform image display or has no display.

S2: Determining target brightness of the light-emitting surface corresponding to the camera area and the display area according to the display state information.

S3: Adjusting the light transmittance of the first adjustment area and/or the light transmittance of the second adjustment area according to the target brightness.

In an embodiment, before step S1, the brightness adjustment method of the display device may further include following steps:

S0: Obtaining a location information of the camera area and a location information of the display area of the display device.

It can be understood that, the location information of the camera area and the location information of the display area may be respective area ranges, so that the light transmittance of the light transmittance adjustment layer can be adjusted in sub-regions subsequently.

The brightness adjustment method of the display device in the display state and the non-display state are respectively described below, and the details are as follows.

When the display state information being acquired is the display state, the step S1 further includes following steps:

S11: Reading an input picture information input to the display device.

It can be understood that, the display device further includes a control terminal. When the display device is in the display state, the control terminal transmits an input picture information for displaying an image to the display panel, the display device can display the image.

Wherein, the input picture information includes but is not limited to gray-scale data of an input picture.

Next, step S2 includes following steps:

S21: Acquiring gray-scale data of the input picture according to the input picture information.

Wherein, the gray-scale data includes a first part of gray-scale data of the input picture corresponding to the camera area, and includes a second part of gray-scale data of the input picture corresponding to the display area.

It can be understood that, even if the display panel has no display corresponding to the camera area, the gray-scale data of the input picture also includes the first part of gray-scale data corresponding to the camera area.

S22: Determining target brightness of the light-emitting surface corresponding to the camera area according to the first part of gray-scale data, and determining target brightness of the light-emitting surface corresponding to the display area according to the second part of gray-scale data.

Next, the step S3 includes following steps:

The light adjustment layer receiving a voltage input from the first driving wirings to adjust the light transmittance of the first adjustment area according to the target brightness of the camera area, and/or the light adjustment layer receiving a voltage input from the second driving wirings to adjust the light transmittance of the second adjustment area according to the target brightness of the display area.

Here, the light adjustment layer is the liquid crystal layer, and the display panel is the OLED display panel, the micro-LED display panel, or the mini-LED display panel as an example for description. Specifically, the light transmittance of the display panel corresponding to the camera area is less than the light transmittance corresponding to the display area. As shown in FIG. 6 and FIG. 7, when the display device is in the display state, the display device can input the corresponding voltage to the first driving wirings 204a according to the target brightness of the camera area 100. The liquid crystal layer inverts the liquid crystals corresponding to the first adjustment area by the first angle through the voltage applied to the first driving wiring 204a, thereby improving the light transmittance of the light transmittance adjustment layer 20 corresponding to the camera area 100. At a same time, the display device can input the corresponding voltage to the second driving wirings 204b according to the target brightness of the display area 200, and the liquid crystal layer inverts the liquid crystals corresponding to the second adjustment area by the second angle through the voltage applied to the second driving wirings 204b, and the light transmittance of the light transmittance adjustment layer 20 corresponding to the display area 200 is reduced. In this way, the brightness transition between the camera area 100 and the display area 200 of the display device can be smooth, the brightness difference between the camera area 100 and the display area 200 of the display device can be reduced or eliminated, and the brightness uniformity of the light-emitting surface of the display device can be realized.

In another embodiment, the display device may input a corresponding voltage to one of the first driving wirings and the second driving wirings, and no voltage is input to another one of the first driving wirings and the second driving wirings. For example, when the liquid crystal layer is not applied with the voltage, the liquid crystal molecules are arranged vertically, which will not affect the light transmittance emitted from the display panel to the light-emitting surface; when the corresponding voltage is input to the second driving wirings, a part of the liquid crystal layer corresponding to the display area is inverted thereby reducing the light transmittance of the second adjustment area of the light transmittance adjustment layer, further, the brightness difference between the camera area and the display area of the display device is reduced or eliminated, and the brightness uniformity of the light-emitting surface of the display device is realized. For another example, the liquid crystal molecules are arranged at a predetermined angle when no voltage is applied to the liquid crystal layer, so that the light transmittance adjustment layer has certain light transmittance. When the corresponding voltage is input to the first driving wirings, the liquid crystal molecules of the liquid crystal layer corresponding to the camera area are inverted and vertically arranged, thereby increasing the light transmittance of the first adjustment area of the light transmittance adjustment layer, further, the brightness difference between the camera area and the display area of the display device is reduced or eliminated, and the brightness uniformity of the light-emitting surface of the display device is realized.

Wherein, when the display state information being acquired is the non-display state, the step S1 further includes following steps:

S11: Reading a preset black picture information.

It can be understood that when the display device is in the non-display state, it can be regarded as a black picture. The display device stores a preset black picture information.

Next, the step S2 includes following steps:

S21: Obtaining gray-scale data of a preset black picture according to the preset black picture information.

It can be understood that, because it is the black picture, the gray-scale data has a same parameter corresponding to different regions.

S22: Determining target brightness of the light-emitting surface corresponding to the camera area and the target brightness of the display area according to the grayscale data.

Wherein, the target brightness of the light-emitting surface corresponding to the camera area is same as the target brightness corresponding to the display area.

Next, the step S3 includes following steps:

The light adjustment layer receiving a voltage input from the first driving wirings to adjust the light transmittance of the first adjustment area according to target brightness of the camera area, and/or the light adjustment layer receiving a voltage input from the second driving wirings to adjust the light transmittance of the second adjustment area according to a target brightness of the display area.

Wherein, a principle of brightness adjustment in the non-display state of the display device is similar to a principle of brightness adjustment in the above-mentioned display state, and details are not described here again.

In conclusion, the display device and the brightness adjustment method of the display device provided by the present invention, the light transmittance adjustment layer is disposed on the side of the display panel close to the light-emitting surface, and the light transmittance adjustment layer includes a first adjustment area corresponding to the camera area and a second adjustment area corresponding to the display area. The light transmittance of the light transmittance adjustment layer can be controlled in the different areas. By adjusting the light transmittance of the first adjustment area and/or the light transmittance of the second adjustment area of the light transmittance adjustment layer, the brightness adjustment of the light-emitting surface of the display device is realized, so that brightness of different areas of the light-emitting surface is kept consistent, the problem of uneven brightness of the light-emitting surface of the display device caused by the difference in light transmittance in the different areas of the display panel can be solved, and the problem of the blind hole corresponding to the camera area of the display device being seen can also be solved.

The embodiments of the present invention have been introduced in detail above, and specific examples are used to illustrate the principles and implementations of the present invention. The descriptions of the above embodiments are only used to help understand the methods and core ideas of the present invention; at the same time, for Those skilled in the art, according to the idea of the present invention, will have changes in the specific embodiments and application scope. To sum up, the content of this specification should not be construed as a limitation of the present invention.

What is claimed is:

1. A display device, wherein the display device comprises a light-emitting surface, the display device comprises a camera area and a display area surrounding the camera area, the display device further comprises:
a display panel;
a light transmittance adjustment layer disposed on a side of the display panel close to the light-emitting surface, and the light transmittance adjustment layer comprising a first adjustment area corresponding to the camera area and a second adjustment area corresponding to the display area;
wherein the display device adjusts a brightness of the light-emitting surface by adjusting a light transmittance of the first adjustment area and/or a light transmittance of the second adjustment area.

2. The display device according to claim 1, wherein the light transmittance adjustment layer comprises a driving wiring layer and a light adjustment layer, and the light adjustment layer receives a voltage input from the driving wiring layer to adjust a light transmittance of the light transmittance adjustment layer.

3. The display device according to claim 2, wherein the driving wiring layer comprises first driving wirings corresponding to the first adjustment area and second driving wirings corresponding to the second adjustment area, and the light adjustment layer receives a voltage input from the first driving wirings and/or a voltage input from the second driving wirings to adjust a light transmittance of a corresponding area of the light transmittance adjustment layer.

4. The display device according to claim 3, wherein the first driving wirings comprise first wirings disposed along a first direction and second wirings arranged along a second direction, the first wirings and the second wirings are located on a same side or different sides of the light adjustment layer, the light adjustment layer receives a voltage input from the first wirings and the second wirings to adjust the light transmittance of the first adjustment area;
the second driving wirings comprise third wirings arranged along a first direction and fourth wirings arranged along a second direction, the third wirings and the fourth wirings are located on a same side or different sides of the light adjustment layer, the light adjustment layer receives a voltage input from the third wirings and the fourth wirings to adjust the light transmittance of the second adjustment area; wherein, the first direction and the second direction are perpendicular to each other.

5. The display device according to claim 2, wherein the light adjustment layer is a liquid crystal layer or an electrochromic layer.

6. The display device according to claim 2, wherein the light transmittance adjustment layer further comprises a first substrate layer and a second substrate layer disposed oppositely, the light adjustment layer is disposed between the first substrate layer and the second substrate layer, and the driving wiring layer is disposed on a surface of a side of at least one of the first substrate layer and the second substrate layer facing the light adjustment layer.

7. A brightness adjustment method of the display device as claimed in claim 1, wherein the brightness adjustment method comprises following steps:
S1: acquiring a display state information of the display device;
wherein, the display state information comprises a display state and a non-display state;
S2: determining a target brightness of the light-emitting surface corresponding to the camera area and the display area according to the display state information;
S3: adjusting the light transmittance of the first adjustment area and/or the light transmittance of the second adjustment area according to the target brightness.

8. The brightness adjustment method of the display device according to claim 7, wherein when the display state information being acquired is the display state, the step S1 further comprises following steps:
S11: reading an input picture information input to the display device;
the step S2 comprises following steps:
S21: acquiring a gray-scale data of an input picture according to the input picture information;
wherein, the gray-scale data comprises a first part of gray-scale data of the input picture corresponding to the camera area and a second part of gray-scale data of the input picture corresponding to the display area;
S22: determining a target brightness of the light-emitting surface corresponding to the camera area according to the first part of gray-scale data, and determining a target brightness of the light-emitting surface corresponding to the display area according to the second part of gray-scale data.

9. The brightness adjustment method of the display device according to claim 8, wherein the light transmittance adjustment layer comprises a driving wiring layer and a light adjustment layer, and the driving wiring layer comprises first driving wirings corresponding to the first adjustment area and second driving wirings corresponding to the second adjustment area, and the S3 comprises following steps:
receiving, by the light adjustment layer, a voltage input from the first driving wiring to adjust the light transmittance of the first adjustment area according to a target brightness of the camera area, and/or receiving, by the light adjustment layer, a voltage input from the second driving wiring to adjust the light transmittance of the second adjustment area according to a target brightness of the display area.

10. The brightness adjustment method of the display device according to claim 7, wherein when the display state information being acquired is the non-display state, the step S1 further comprises following steps:
S11: reading a preset black picture information;
the step S2 comprises following steps:
S21: obtaining a gray-scale data of a preset black picture according to the preset black picture information;
S22: determining the target brightness of the light-emitting surface corresponding to the camera area and the display area according to the grayscale data.

11. The brightness adjustment method of the display device according to claim 10, wherein the light transmittance adjustment layer comprises a driving wiring layer and a light adjustment layer, and the driving wiring layer comprises first driving wirings corresponding to the first adjustment area and second driving wirings corresponding to the second adjustment area, the S3 comprises following steps:
receiving, by the light adjustment layer, a voltage input from the first driving wirings to adjust the light transmittance of the first adjustment area according to the target brightness of the camera area, and/or receiving, by the light adjustment layer, a voltage input from the second driving wirings to adjust the light transmittance of the second adjustment area according to the target brightness of the display area.

12. A display device, wherein the display device comprises a light-emitting surface, the display device comprises a camera area and a display area surrounding the camera area, the display device further comprises:
a display panel;
a light transmittance adjustment layer disposed on a side of the display panel close to the light-emitting surface, and the light transmittance adjustment layer comprising a first adjustment area corresponding to the camera area and a second adjustment area corresponding to the display area;
wherein, a light transmittance of the first adjustment area and a light transmittance of the second adjustment area can be adjusted independently, the display device adjusts a brightness of the light-emitting surface by adjusting a light transmittance of the first adjustment area and/or a light transmittance of the second adjustment area.

13. The display device according to claim 12, wherein the light transmittance adjustment layer comprises a driving wiring layer and a light adjustment layer, and the light adjustment layer receives a voltage input from the driving wiring layer to adjust a light transmittance of the light transmittance adjustment layer.

14. The display device according to claim 13, wherein the driving wiring layer comprises first driving wirings corresponding to the first adjustment area and second driving wirings corresponding to the second adjustment area, and the light adjustment layer receives a voltage input from the first driving wirings and/or a voltage input from the second driving wirings to adjust a light transmittance of a corresponding area of the light transmittance adjustment layer.

15. The display device according to claim 14, wherein the first driving wirings comprise first wirings arranged along a first direction and second wirings arranged along a second direction, the first wirings and the second wirings are located on a same side or different sides of the light adjustment layer, the light adjustment layer receives a voltage input from the first wirings and a voltage input from the second wiring to adjust the light transmittance of the first adjustment area;
the second driving wirings comprises third wirings arranged along a first direction and fourth wirings arranged along a second direction, the third wirings and the fourth wirings are located on a same side or different sides of the light adjustment layer, the light adjustment layer receives a voltage input from the third wiring and a voltage input from the fourth wirings to adjust the light transmittance of the second adjustment area; wherein, the first direction and the second direction are perpendicular to each other.

16. The display device according to claim 13, wherein the light adjustment layer is a liquid crystal layer or an electrochromic layer.

17. The display device according to claim 13, wherein the light transmittance adjustment layer further comprises a first substrate layer and a second substrate layer disposed oppositely, the light adjustment layer is disposed between the first substrate layer and the second substrate layer, and the driving wiring layer is disposed on a surface of a side of at least one of the first substrate layer and the second substrate layer facing the light adjustment layer.
